(19) United States
(12) Patent Application Publication
(10) Pub. No.: US 2009/0107709 A1
(43) Pub. Date: Apr. 30, 2009

(54) Printed circuit board and manufacturing method thereof

(75) Inventors: Jee-Soo MOK, Yongin-si (KR); Je-Gwang YOO, Yongin-si (KR); Eung-Suek LEE, Ansan-si (KR); Chang-Sup RYU, Yongin-si (KR)

Correspondence Address: STAAS & HALSEY LLP, SUITE 700, 1201 NEW YORK AVENUE, N.W., WASHINGTON, DC, 20005, US

(73) Assignee: SAMSUNG ELECTRO-MECHANICS CO., LTD., Suwon (KR)

(21) Appl. No.: 12/078,576

(22) Filed: Apr. 1, 2008

(30) Foreign Application Priority Data
Oct. 26, 2007 (KR) 10-2007-0108384

(51) Int. Cl. H05K 1/09; H05K 3/00

(52) U.S. Cl. 174/257; 29/847

(57) ABSTRACT

A printed circuit board and a method of manufacturing the printed circuit board are disclosed. The printed circuit board may include: an insulation layer, a circuit pattern formed on an upper surface and a lower surface of the insulation layer, and a bump penetrating the insulation layer such that the circuit pattern is electrically connected, where an alloy layer, which is configured to increase contact between the circuit pattern and the bump, may be interposed between the bump and the circuit pattern.

### CROSS-REFERENCE TO RELATED APPLICATIONS

This application claims the benefit of Korean Patent Application No. 10-2007-0108384 filed with the Korean Intellectual Property Office on Oct. 26, 2007, the disclosure of which is incorporated herein by reference in its entirety.

### BACKGROUND

1. Technical Field

The present invention relates to a printed circuit board that utilizes bumps, and to a method of manufacturing the printed circuit board.

2. Description of the Related Art

With developments in electronic components, there is a growing demand for technology that can improve the performance of the HDI (high density interconnection) board, which employs interlayer electrical connection of circuit patterns and fine-lined circuit wiring to provide a printed circuit board of a higher density. That is, to improve the performance of the HDI board, there is a need for advanced technology in interlayer electrical connection for circuit patterns and technology that provides a higher degree of freedom in circuit design. A method of manufacturing a multilayered printed circuit board according to the related art may include drilling, forming plating layers by chemical and electrical copper plating, and forming circuit layers. However, this conventional method does not satisfy the demands for lower costs, which accompany the trends towards decreasing prices of the products to which the board is applied, or the demands for reduced lead times, which are needed for increased workability in mass production. As such, a new manufacturing process is required that is capable of meeting such demands.

A method of interconnecting layers using conductive paste has been proposed and commercialized as a possible alternative to the method according to the related art described above. However, the interconnection implemented by the commercialized method of using conductive paste entails higher specific resistance compared to the interconnection implemented using copper plating, as well as lower adhesion to the copper foil layers.

### SUMMARY

One aspect of the invention provides a printed circuit board and a method of manufacturing the printed circuit board, in which the specific resistance is lowered at the contact surfaces between the metal layers and the bumps.

Another aspect of the invention provides a printed circuit board that includes: an insulation layer, a circuit pattern formed on an upper surface and a lower surface of the insulation layer, and a bump penetrating the insulation layer such that the circuit pattern is electrically connected, where an alloy layer, which is configured to increase contact between the circuit pattern and the bump, is interposed between the bump and the circuit pattern.

The alloy layer may contain copper and tin and can be, for example, Cu₆Sn₅ or CuSn₃.

Still another aspect of the invention provides a method of manufacturing a printed circuit board, where the method includes: forming a bump, which is made from a paste containing silver powder, silver flakes, and tin powder, on a first metal layer; stacking an insulation layer over the first metal layer, such that the bump penetrates the insulation layer; stacking a second metal layer over the insulation layer while applying heat and pressure, such that the first metal layer and the second metal layer are electrically connected by the bump; and forming a circuit pattern by removing portions of the first and second metal layers.

Stacking the second metal layer may further include applying heat, such that an alloy layer of copper and tin may be formed at a contact surface between the first metal layer and the bump and at a contact surface between the second metal layer and the bump.

The alloy layer may contain copper and tin and can be, for example, Cu₆Sn₅ or CuSn₃.

Additional aspects and advantages of the present invention will be set forth in part in the description which follows, and in part will be obvious from the description, or may be learned by practice of the invention.

### BRIEF DESCRIPTION OF THE DRAWINGS

FIG. 1 is a flowchart for a method of manufacturing a printed circuit board according to an embodiment of the present invention.

FIG. 2, FIG. 3, FIG. 4, FIG. 5, and FIG. 6 are cross-sectional views representing a flow diagram for a method of manufacturing a printed circuit board according to an embodiment of the present invention.

FIG. 7 is a cross-sectional view of a printed circuit board according to another embodiment of the present invention.

### DETAILED DESCRIPTION

The printed circuit board and manufacturing method thereof, according to certain embodiments of the invention, will be described below in more detail with reference to the accompanying drawings. Those components that are the same or are in correspondence are rendered the same reference numeral regardless of the figure number, and redundant explanations are omitted.

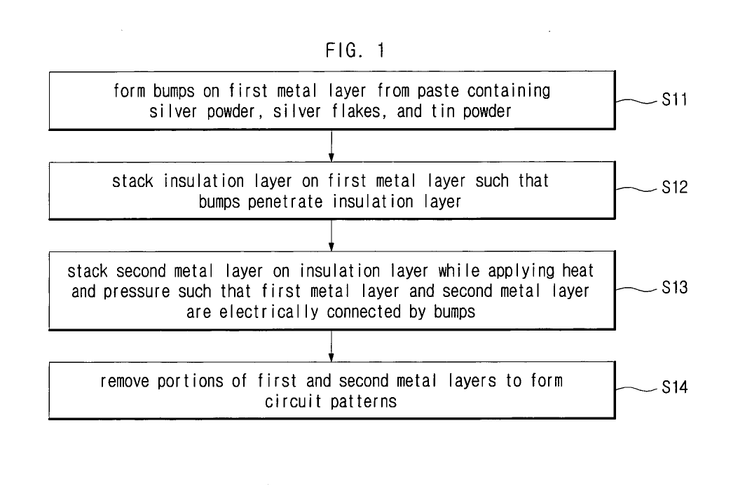

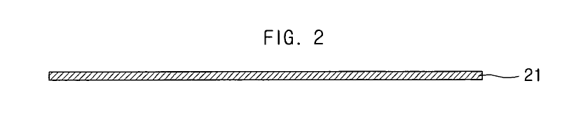

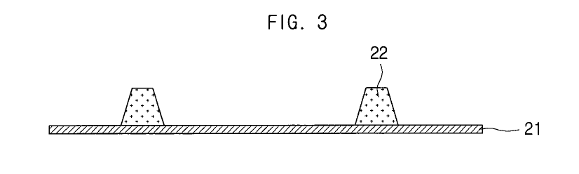

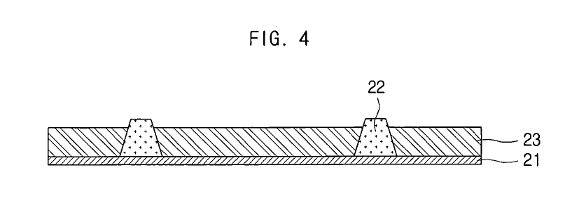

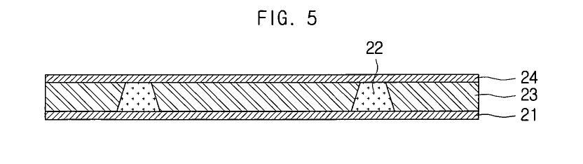

FIG. 1 is a flowchart for a method of manufacturing a printed circuit board according to an embodiment of the present invention, and FIG. 2 through FIG. 6 are cross-sectional views representing a flow diagram for a method of manufacturing a printed circuit board according to an embodiment of the present invention. In FIGS. 2 to 6, there are illustrated a first metal layer 21, bumps 22, an insulation layer 23, a second metal layer 24, circuit patterns 25, and alloy layers 26.

Operation S11 may include forming bumps on a first metal layer from a paste containing silver powder, silver flakes, and tin powder.

A copper foil may generally be used for the first metal layer 21, but any of various other materials may also be used if it is a metal that provides conductivity.

In this operation, the paste can be formed as bumps 22 on the upper surface of the first metal layer 21 using a mask. Silver (Ag) powder, silver flakes, and tin (Sn) powder can be included in the paste. In order to maintain a paste-like state, an epoxy binder, dispersing agent, etc., may also be included.

When the bumps 22 are formed, as shown in FIG. 3, a curing operation may be proceeded with. The bumps 22 may be maintained to have a degree of rigidity that enables the bumps 22 to penetrate an insulation layer 23.

Operation S12 may include stacking an insulation layer onto the first metal layer such that the bumps penetrate the insulation layer, where FIG. 4 illustrates an example of a corresponding process.

Prepreg may generally be used for the insulation layer 23. Of course, any of various other materials may also be used if it is a nonconductive material. The rigidity of the insulation layer 23 can be lower than the rigidity of the bumps 22. When the insulation layer 23 is stacked over the first metal layer 21, the bumps 22 may penetrate the insulation layer 23, as illustrated in FIG. 4.

Operation S13 may include stacking a second metal layer over the insulation layer while applying heat and pressure, such that the first metal layer and the second metal layer may be electrically connected by the bumps. FIG. 5 illustrates an example of a corresponding process.

The second metal layer 24 can be of the same material as that of the first metal layer 21. When the second metal layer 24 is stacked onto the insulation layer 23 while applying heat and pressure, the first metal layer 21 and the second metal layer 24 can be electrically connected by the bumps 22. The bumps 22 may contain tin. Because tin melts at a relatively low temperature, it can easily bond with other metals to form alloy layers 26.

In particular, as illustrated in FIG. 6, the alloy layers 26 may be formed at the interface between the first metal layer 21 and the bumps 22, as well as at the interface between the second metal layer 24 and the bumps 22. An alloy layer 26 can include Cu₆Sn₅ or CuSn₃. These alloy layers 26 allow close bonding between the bumps 22 and the metal layers 21, 24, and thus increase contact. As a result, the specific resistance of the bumps 22 can be lowered.

Operation S14 may include removing portions of the first and second metal layers to form circuit patterns. Removing the portions of the first and second metal layers 21, 24 by etching can result in the forming of the circuit patterns 25.

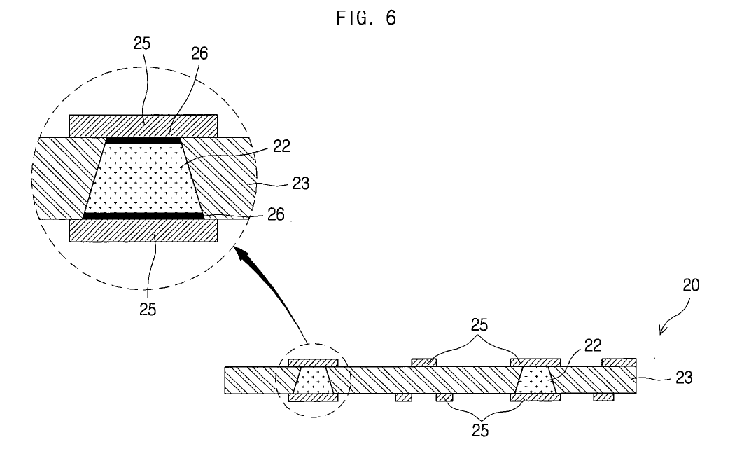

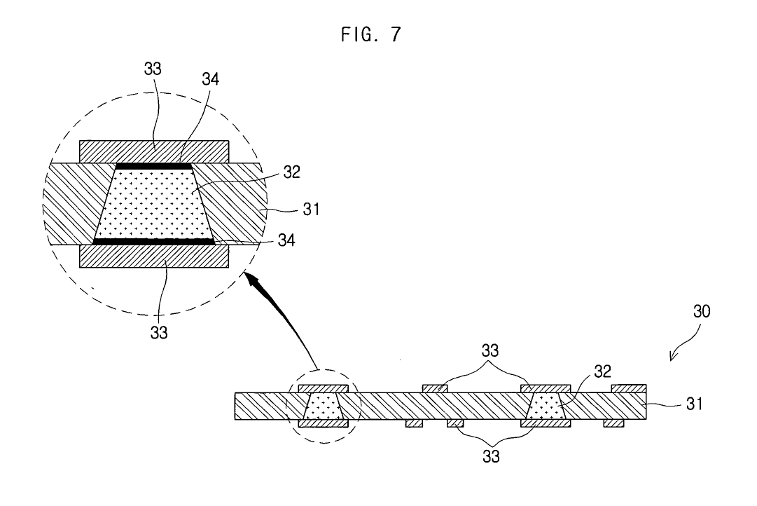

FIG. 7 is a cross-sectional view of a printed circuit board according to another embodiment of the present invention. In FIG. 7, there are illustrated a printed circuit board 30, an insulation layer 31, bumps 32, circuit patterns 33, and alloy layers 34.

The printed circuit board 30 may include circuit patterns 33 formed on the upper and lower surfaces of the insulation layer 31, where these circuit patterns 33 may be electrically connected by way of bumps 32. The bumps 32 can contain silver powder, silver flakes, and tin powder. In addition, an epoxy binder may further be included.

Alloy layers 34 may be formed between the bumps 32 and the circuit patterns 33. An alloy layer 34 can include copper and tin as major constituents. The chemical formula of an alloy layer 34 can be Cu₆Sn₅ or CuSn₃.

By having alloy layers 34 interposed between the bumps 32 and the circuit patterns 33, the bumps 32 and the circuit patterns 33 can be placed in closer contact, and the electrical flow can be improved, so that the specific resistance of the bumps 32 may be lowered.

The method of forming such alloy layers 34 between the bumps 32 and circuit patterns 33 are as already described in the embodiment illustrated in FIGS. 2 to 6.

According to certain aspects of the invention as set forth above, by manufacturing a printed circuit board with alloy layers interposed between the metal layers and the bumps, the circuit patterns on different layers can be electrically connected with higher reliability. Consequently, the resistance can be lowered at the connection portions between the bumps and the circuit patterns.

While the spirit of the invention has been described in detail with reference to particular embodiments, the embodiments are for illustrative purposes only and do not limit the invention. It is to be appreciated that those skilled in the art can change or modify the embodiments without departing from the scope and spirit of the invention.

What is claimed is:

1. A printed circuit board comprising:
an insulation layer;
a circuit pattern formed on an upper surface and a lower surface of the insulation layer; and
a bump penetrating the insulation layer such that the circuit pattern is electrically connected,
wherein an alloy layer is interposed between the bump and the circuit pattern, the alloy layer configured to increase contact between the circuit pattern and the bump.

2. The printed circuit board of claim 1, wherein the alloy layer contains copper and tin.

3. The printed circuit board of claim 2, wherein the alloy layer contains Cu₆Sn₅.

4. The printed circuit board of claim 2; wherein the alloy layer contains CuSn₃.

5. A method of manufacturing a printed circuit board, the method comprising:
forming a bump on a first metal layer, the bump made from a paste containing silver powder, silver flakes, and tin powder;
stacking an insulation layer over the first metal layer such that the bump penetrates the insulation layer;
stacking a second metal layer over the insulation layer while applying heat and pressure such that the first metal layer and the second metal layer are electrically connected by the bump; and
forming a circuit pattern by removing portions of the first and second metal layers.

6. The method of claim 5, wherein stacking the second metal layer further comprises:
applying heat such that an alloy layer of copper and tin is formed at a contact surface between the first metal layer and the bump and at a contact surface between the second metal layer and the bump.

7. The method of claim 6, wherein the alloy layer of copper and tin includes Cu₆Sn₅.

8. The method of claim 6, wherein the alloy layer of copper and tin includes CuSn₃.
